(19) United States
(12) Patent Application Publication
(10) Pub. No.: US 2022/0294186 A1
(43) Pub. Date: Sep. 15, 2022

(54) LASER DEVICE

(71) Applicant: Rayir, Co., Suwon-si (KR)

(72) Inventors: Won Jin CHOI, Suwon-si (KR); Dong Hwan KIM, Seoul (KR)

(73) Assignee: Rayir, Co., Suwon-si (KR)

(21) Appl. No.: 17/394,433

(22) Filed: Aug. 5, 2021

(30) Foreign Application Priority Data
Mar. 9, 2021 (KR) 10-2021-0030728

(51) Int. Cl. H01S 5/20; H01S 5/22

(52) U.S. Cl. CPC H01S 5/2027; H01S 5/2207; H01S 5/221; H01S 5/2209

(57) ABSTRACT

Provided is a laser device including a lower reflective layer, a laser cavity comprising an active layer disposed on the lower reflective layer, an upper reflective layer disposed on the laser cavity, and a blocking structure disposed between the laser cavity and the upper reflective layer, in which the blocking structure includes a first intermediate layer disposed on the laser cavity, a blocking layer disposed on the first intermediate layer and including a through-hole, and a second intermediate layer disposed on the blocking layer.

### RELATED APPLICATION

This application claims the benefit of priority of Korean Patent Application No. 10-2021-0030728 filed on Mar. 9, 2021, the contents of which are incorporated herein by reference in their entirety.

### FIELD AND BACKGROUND OF THE INVENTION

Embodiments of the present invention relate to a laser device.

A vertical cavity surface emitting laser (VCSEL) is capable of single longitudinal mode oscillation of a narrow spectrum and has a small radiation angle of a beam and thus a high coupling efficiency.

Recently, research is being actively carried out on a technique for manufacturing a light source matrix by patterning the VCSEL in a two-dimensional (2D) array form. A three-dimensional (3D) image of an object may be formed by irradiating the light source matrix patterned in the 2D array form to an object and analyzing a pattern of reflected light.

A significant advance in currently commercially used VCSELs has been achieved by the introduction of an oxide aperture.

The oxide aperture may be formed by an oxidation process in which an AlGaAs material is deformed into an AlOx:As form as a result of a chemical reaction with the AlGaAs material, as an AlGaAs layer is exposed to a high-temperature N₂ and H₂O mixed gas atmosphere and thus H₂O molecules go through a diffusion process inside the AlGaAs layer.

Such a chemical oxidation process may greatly depend on processing conditions such as Al content, water vapor content, temperature of a reaction chamber, etc., of the AlGaAs layer, making it difficult to precisely control horizontal shape and size of the oxide aperture.

Moreover, a high-density defect may occur in an interfacial surface between an oxide layer and the oxide aperture, resulting in a reliability problem due to vulnerability to electro static discharge (ESD).

### SUMMARY OF THE INVENTION

Embodiments of the present invention provide a laser device that is resistant to electro static discharge (ESD).

Moreover, embodiments of the present invention provide a laser device from which an oxide aperture is omitted.

Problems to be solved in embodiments are not limited thereto, and may include objects or effects that may be understood from solutions to the problems or embodiments described below.

According to an aspect of the present invention, a laser device includes a lower reflective layer, a laser cavity comprising an active layer disposed on the lower reflective layer, an upper reflective layer disposed on the laser cavity, and a blocking structure disposed between the laser cavity and the upper reflective layer, in which the blocking structure includes a first intermediate layer disposed on the laser cavity, a blocking layer disposed on the first intermediate layer and including a through-hole, and a second intermediate layer disposed on the blocking layer.

The first intermediate layer, the second intermediate layer, and the blocking layer may include any one of a dopant doped in the lower reflective layer or a dopant doped in the upper reflective layer, the first intermediate layer and the second intermediate layer may include a same dopant, and the blocking layer may include a dopant that is different from a dopant of the first intermediate layer.

A thickness of the second intermediate layer may be less than a thickness of the blocking layer, and an aluminum composition of the blocking layer may be higher than an aluminum composition of the second intermediate layer.

The laser device may further include a third intermediate layer disposed on the second intermediate layer, and the third intermediate layer may include a first area disposed on the second intermediate layer and a second area disposed on the through-hole.

A thickness of the blocking layer may be greater than a thickness of the first area and may be less than a thickness of the second area.

A top surface of the third intermediate layer may include a flat surface.

The second intermediate layer may be a lowermost layer of the upper reflective layer.

The first intermediate layer may be a p-type semiconductor layer, the blocking layer may be an n-type semiconductor layer, and the second intermediate layer may be a p-type semiconductor layer.

The first intermediate layer may be an n-type semiconductor layer, the blocking layer may be a p-type semiconductor layer, and the second intermediate layer may be an n-type semiconductor layer.

Oxidation degrees of the first intermediate layer, the blocking layer, and the second intermediate layer may be less than or equal to 10%.

The through-hole may be provided in plural.

The laser device may further include a blocking area where the blocking layer and the upper reflective layer overlap with each other and a transmitting area where the through-hole and the upper reflective layer overlap with each other, and an effective refractive index difference between the blocking area and the transmitting area may be greater than or equal to 0.001.

### BRIEF DESCRIPTION OF THE SEVERAL VIEWS OF THE DRAWINGS

FIG. 1 is a conceptual view of a laser device according to an embodiment of the present invention;

FIG. 2 is a view showing a laser device having an oxide aperture;

FIG. 3A is a view showing a light output variation with respect to a size of an oxide aperture;

FIG. 3B is a view showing a light output variation with respect to a thickness of an oxide;

FIG. 4 shows a simulation result of an effective refractive index difference with respect to a thickness of a blocking layer;

FIG. 5 is a conceptual view of a laser device according to another embodiment of the present invention;

FIG. 6 is a circuit diagram of a laser device according to an embodiment of the present invention;

FIG. 7 shows a simulation result of measurement of a leakage current variation with respect to a thickness of a current blocking layer;

FIGS. 8, 9 and 10 are views showing a method for manufacturing a laser device, according to an embodiment of the present invention;

FIG. 11 is a conceptual view of a laser device according to another embodiment of the present invention;

FIG. 12 is a partially enlarged view of FIG. 11; and

FIG. 13 is a cross-sectional view taken along A-A of FIG. 12.

### DESCRIPTION OF SPECIFIC EMBODIMENTS OF THE INVENTION

Various changes may be made to the present invention and the present invention may have various embodiments which will be illustrated in the drawings and described in detail in the detailed description. However, such a description is not construed as limited to specified embodiments, and include all changes, equivalents, or substitutes included in the spirit and technical scope of the present invention.

Although ordinal numbers such as “first”, “second”, and so forth will be used to describe various components of the present invention, those components are not limited by the terms. These terms may be used for the purpose of distinguishing one component from another component. For example, a second component may also be named as a first component without departing from the right scope of the present invention, and similarly, the first component may also be named as the second component. The term “and/or” used herein includes any and all combinations of one or more of the associated listed items.

When a component is referred to as being “connected” or “accessed” to or by any other component, it should be understood that the component may be directly connected or accessed by the other component, but another new component may also be interposed between them. Contrarily, when a component is referred to as being “directly connected” or “directly joined” to or by any other component, it should be understood that there is no component between the component and the other component.

The terms used in the present application are for the purpose of describing particular exemplary embodiments only and are not intended to be limiting. As used herein, the singular forms are intended to include the plural forms as well, unless the context clearly indicates otherwise. It will be further understood that the terms “comprises” and/or “has,” when used in this application, specify the presence of a stated feature, number, step, operation, component, element, or combination thereof, but do not preclude the presence or addition of one or more other features, numbers, steps, operations, components, elements, or combinations thereof.

All of the terms used in the present application including technical or scientific terms have the same meanings as those generally understood by those of ordinary skill in the art unless they are defined otherwise. The terms defined in a generally used dictionary should be interpreted as having meanings that are the same as or similar with the contextual meanings of the relevant technology and should not be interpreted as having ideal or exaggerated meanings unless they are clearly defined in the present application.

Hereinafter, an embodiment will be described in detail with reference to the accompanying drawings, and regardless of figure symbols, the same component or corresponding components will be given the same reference numeral and a redundant description will not be provided.

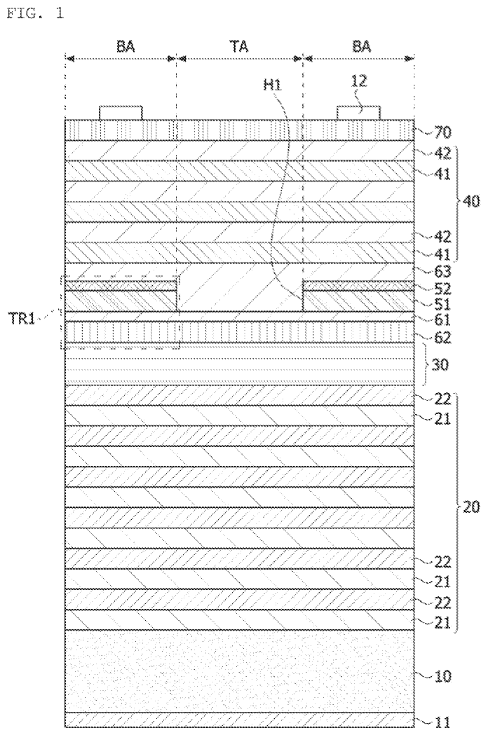

FIG. 1 is a conceptual view of a laser device according to an embodiment of the present invention.

Referring to FIG. 1, a laser device according to an embodiment of the present invention may include a lower reflective layer 20 disposed on a substrate 10, a laser cavity 30 disposed on the lower reflective layer 20, a blocking structure TR1 including a through-hole H1 disposed in a center thereof, and an upper reflective layer 40 disposed on the blocking structure TR1. The laser device according to an embodiment of the present invention may be a vertical cavity surface emitting laser (VCSEL), but may also be various laser devices or light-emitting diodes (LEDs) without being necessarily limited to the VCSEL.

A semiconductor structure of the laser device may be manufactured using, but not limited to, metal-organic chemical vapor deposition (MOCVD), liquid phase epitaxy (LPE), molecular beam epitaxy (MBE), etc.

The substrate 10 may be a semi-insulating or conductive substrate. For example, the substrate 10 may be a GaAs substrate with a high doping concentration that may be about 1×10¹⁷ cm³ to about 1×10¹⁹ cm³. Depending on a need, a semiconductor buffer layer such as an AlGaAs or GaAs thin film may be further disposed on the substrate 10, but the present invention is not necessarily limited thereto.

The lower reflective layer 20 may include a distributed Bragg reflector (DBR) of an n-type superlattice structure. The lower reflective layer 20 may be epitaxially deposited on the substrate 10 using MOCVD, MBE, etc.

The lower reflective layer 20 may perform internal reflection in a VCSEL structure. The lower reflective layer 20 may be formed by alternately stacking a plurality of first lower reflective layers 21 and a plurality of second lower reflective layers 22. Both the first lower reflective layer 21 and the second lower reflective layer 22 may be AlGaAs, but an aluminum composition ratio of the first lower reflective layer 21 may be higher than that of the second lower reflective layer 22. However, without being limited to the above, the first lower reflective layer 21 and the second lower reflective layer 22 may include semiconductor layers having various refractive indices to function as reflective layers.

The first lower reflective layer 21 and the second lower reflective layer 22, which form the lower reflective layer 20, may preferably have an effective optical thickness that is about 1/4 of a wavelength of light generated by the VCSEL. The lower reflective layer 20 may preferably have a reflectivity of about 100% with respect to light emitted from the laser cavity 30 for high internal reflection of the VCSEL.

The first lower reflective layer 21 and the second lower reflective layer 22 may have an effective optical thickness (target light wavelength/(4×reflectivity of a material)) that is about ¼ of the wavelength of the light generated by the VCSEL.

The reflectivity of the lower reflective layer 20 may be determined by a refractive index difference between the first lower reflective layer 21 and the second lower reflective layer 22 and the number of stacks of the first lower reflective layer 21 and the second lower reflective layer 22. Therefore, a high reflectivity may be obtained by a large refractive index difference and a great number of stacks.

To reduce an electric resistance, an Al graded AlGaAs layer that one-dimensionally or two-dimensionally continuously changes aluminum compositions of the first lower reflective layer 21 and the second lower reflective layer 22 may be positioned between the first lower reflective layer 21 and the second lower reflective layer 22.

The laser cavity 30 may include an active layer including one or more quantum well layers and barrier layers. The quantum well layer may be any one selected from GaAs, AlGaAs, AlGaAsSb, InAlGaAs, AlInGaP, GaAsP, or InGaAsP, and the barrier layer may be any one selected from AlGaAs, InAlGaAs, InAlGaAsP, AlGaAsSb, GaAsP, GaInP, AlInGaP, or InGaAsP.

The laser cavity 30 may be designed to provide a sufficient optical gain of the laser device. For example, the laser cavity 30 according to an embodiment of the present invention may include, in the center thereof, a quantum well layer having sufficient thickness and composition ratio for emission of light with a wavelength band of about 850 nm or about 980 nm.

However, a wavelength band of laser output from the quantum well layer is not specially limited.

The laser cavity 30 may include a first clad layer (not shown) disposed under the active layer and a second clad layer (not shown) disposed on the active layer. The first clad layer may be an n-type semiconductor layer and the second clad layer may be a p-type semiconductor layer, without being necessarily limited thereto. The first clad layer and the second clad layer may not be doped with a dopant. For example, the first clad layer and the second clad layer may be AlGaAs, without being necessarily limited thereto.

The blocking structure TR1 may be disposed on the laser cavity 30. The blocking structure TR1 may include the through-hole H1 formed vertically. The through-hole H1 may completely or partially penetrate the blocking structure TR1 in the vertical direction.

The blocking structure TR1 may block current injected to the laser cavity 30 and light emitted from the laser cavity 30. That is, the blocking structure TR1 may serve as an oxide layer of the VCSEL. The through-hole H1 may serve as a window through which current and light pass.

The blocking structure TR1 may include a plurality of semiconductor layers. For example, the blocking structure TR1 may include a semiconductor structure of a transistor or a thyristor capable of shielding movement of current.

For example, the blocking structure TR1 may include a first intermediate layer 61, a blocking layer 51, and a second intermediate layer 52. The first intermediate layer 61 and the second intermediate layer 52 may be p-type semiconductor layers doped with a p-type dopant, and the blocking layer 51 may be an n-type semiconductor layer doped with an n-type dopant.

However, without being limited to the above, the first intermediate layer 61 and the second intermediate layer 52 may be n-type semiconductor layers doped with an n-type dopant, and the blocking layer 51 may be a p-type semiconductor layer doped with a p-type dopant. Moreover, the number of semiconductor layers forming the blocking structure TR1 may further increase.

That is, the blocking structure TR1 may have any one of various semiconductor stacking structures such as a PNP type, an NPN type, a PNPN type, an NPNP type, etc. To block current and light in a blocking area BA, the number of layers constituting the blocking structure TR1 may be properly adjusted.

Current may flow in the blocking structure TR1 after a separate gate voltage is applied to the blocking layer 51 that corresponds to a base in terms of a structure of a transistor. However, according to an embodiment of the present invention, a separate voltage is not applied to the blocking layer 51 that corresponds to the base of the transistor, such that the blocking structure TR1 may serve to substantially block the current.

The first intermediate layer 61 may be disposed on the laser cavity 30. The first intermediate layer 61 may be doped with a p-type dopant. The first intermediate layer 61 may be a semiconductor layer having the same composition as that of the upper reflective layer 40.

The first intermediate layer 61 may be disposed on the laser cavity 30 to prevent the laser cavity 30 from being exposed when the through-hole H1 is formed in the blocking structure TR1. The first intermediate layer 61 may also serve as an etching stop layer. However, without being necessarily limited to the above, the first intermediate layer 61 may be a second clad layer disposed on the active layer in the laser cavity 30.

The first intermediate layer 61 may be any one selected from GaAs, AlGaAs, InAlGaAs, AlInGaP, GaAsP, or InGaAsP, doped with a p-type dopant. The first intermediate layer 61 is exposed to the outside in the formation of the through-hole H1, such that the composition of Al may be controlled to be low to minimize oxidation. For example, the first intermediate layer 61 may be GaAs.

At least one sub-intermediate layer 62 may be further disposed between the first intermediate layer 61 and the laser cavity 30. In a structure where such a sub-intermediate layer is disposed, the through-hole H1 may be formed also in the first intermediate layer 61. The sub-intermediate layer 62 may be a semiconductor layer having the same composition as that of the upper reflective layer 40.

The blocking layer 51 may be disposed on the first intermediate layer 61, and may be doped with a dopant that is different from that of the first intermediate layer 61. For example, the blocking layer 51 may be doped with an n-type dopant. When the first intermediate layer 61 is doped with an n-type dopant, the blocking layer 51 may be doped with a p-type dopant.

The blocking layer 51 may be any one selected from GaAs, AlGaAs, AlAs, InAlGaAs, AlInGaP, AlInP, AlGaP, AlGaAsP, GaAsP, AlP, ZnSe, ZnSeS, or InGaAsP.

The second intermediate layer 52 may be disposed on the blocking layer 51. A dopant doped in the second intermediate layer 52 may be the same as that of the first intermediate layer 61, but may be different from that of the blocking layer 51. For example, the second intermediate layer 52 may be any one selected from GaAs, AlGaAs, InAlGaAs, AlInGaP, GaAsP, ZnSe, ZnSeS, or InGaAsP, doped with a p-type dopant.

The second intermediate layer 52 may be a capping layer that prevents the blocking layer 51 having a high aluminum (Al) composition from being oxidized by being exposed to the outside. The second intermediate layer 52 may have a lower Al composition than that of the blocking layer 51. For example, the second intermediate layer 52 may be a GaAs layer.

When the first intermediate layer 61 and the second intermediate layer 52 are formed of GaAs, the blocking layer 51 may be formed of AlGaAs or AlAs. When the blocking layer 51 is formed of GaAs, it may have the same composition as those of the first intermediate layer 61 and the second intermediate layer 52, degrading current blocking efficiency. When the Al composition of the blocking layer 51 is about 80% through about 100%, the blocking layer 51 may have a sufficient current blocking efficiency. In addition, the thickness of the blocking layer 51 may be greater than those of the first intermediate layer 61 and the second intermediate layer 52.

The through-hole H1 formed in the blocking structure TR1 may be formed in the blocking layer 51, but may also be formed in the blocking layer 51 and the second intermediate layer 52, without being necessarily limited to the above. Alternatively, through-holes may be formed in all of the first intermediate layer 61, the blocking layer 51, and the second intermediate layer 52.

The blocking structure TR1 may have a semiconductor stacking structure of a PNP type, an NPN type, a PNPN type, or an NPNP type, thereby blocking current. Moreover, when the first intermediate layer 61 and the second intermediate layer 52 are GaAs layers, whereas when the blocking layer 51 is an AlGaAs layer, light may be blocked due to different refractive indices. However, the present invention is not limited to the above, such that various materials of a lower refractive index than that of a GaAs layer may be applied without a limitation to improve the light blocking efficiency.

The blocking structure TR1, due to a relatively high resistance and a relatively low refractive index thereof, may pass current through the through-hole H1 and concentrate laser light at the center of the device. That is, an area overlapping with the blocking structure TR1 may be defined as the blocking area BA, and an area overlapping with the through-hole H1 may be defined as a transmitting area TA.

A third intermediate layer 63 may be formed on the blocking structure TR1. The third intermediate layer 63 may include a first area (the blocking area BA) disposed on the second intermediate layer 52 and a second area (the transmitting area TA) disposed in the through hole H1. The third intermediate layer 63 may be a planarization layer. Thus, a top surface of the third intermediate layer 63 may have a flat surface.

In the third intermediate layer 63, an optical thickness of the second area may have 1, 3, 5, 7, 9, and 11 quarter wave optical thickness (QWOT) coefficients of an emission wavelength. For example, the optical thickness of the second area may have a 7 QWOT coefficient of the emission wavelength. Thus, the thickness of the blocking layer 51 may be greater than that of the first area of the third intermediate layer 63 and may be less than that of the second area of the third intermediate layer 63. A sum of the thicknesses of the blocking layer 51, the second intermediate layer 52, and the first area may be equal to the thickness of the second area.

The upper reflective layer 40 may be disposed on the blocking structure TR1. The upper reflective layer 40 may include a first upper reflective layer 41 and a second upper reflective layer 42 identically to the lower reflective layer 20.

Both the first upper reflective layer 41 and the second upper reflective layer 42 may have an AlGaAs composition, but an A1 composition of the first upper reflective layer 41 may be higher than that of the second upper reflective layer 42.

The upper reflective layer 40 may be doped to have a polarity that is different from that of the lower reflective layer 20. For example, when the lower reflective layer 20 and the substrate 10 are doped with an n-type dopant, the upper reflective layer 40 may be doped with a p-type dopant.

The upper reflective layer 40 may include a smaller number of layers than the lower reflective layer 20 to reduce a reflectivity from the VCSEL. That is, the reflectivity of the upper reflective layer 40 may be less than that of the lower reflective layer 20.

The first electrode 12 may be disposed on the upper reflective layer 40, and the second electrode 11 may be disposed under the substrate 10. However, without being necessarily limited to the above, an upper portion of the substrate 10 of the second electrode 11 may be exposed and the first electrode 12 may be disposed on an exposed area.

The first electrode 12 and the second electrode 11 may be formed by including at least one of, but not limited to, indium tin oxide (ITO), indium zinc oxide (IZO), indium zinc tin oxide (IZTO), indium aluminum zinc oxide (IAZO), indium gallium zinc oxide (IGZO), indium gallium tin oxide (IGTO), aluminum zinc oxide (AZO), antimony tin oxide (ATO), gallium zinc oxide (GZO), IZO nitride (IZON), Al—Ga ZnO (AGZO), In—Ga ZnO (IGZO), ZnO, IrOx, RuOx, NiO, RuOx/ITO, Ni/IrOx/Au, Ni/IrOx/Au/ITO, Ag, Ni, Cr, Ti, Al, Rh, Pd, Ir, Sn, In, Ru, Mg, Zn, Pt, Au, or Hf.

For example, the first electrode 12 may include a plurality of metal layers (e.g., Ti/Pt/Au). In this case, the thickness of Ti may be about 100 angstroms through about 400 angstroms, and the thickness of Au may be about 3000 angstroms through about 20000 angstroms, without being necessarily limited thereto.

The second electrode 11 may include a plurality of metal layers (e.g., AuGe/Ni/Au). The thickness of AuGe may be about 1000 angstroms, the thickness of Ni may be about 100 angstroms, and the thickness of Au may be about 2000 angstroms, without being necessarily limited thereto.

An ohmic layer 70 may be further disposed between the first electrode 12 and the upper reflective layer 40. The ohmic layer 70 may include a material for a low ohmic resistance, which has a band gap that is the same as or lower than that of the GaAs substrate 10 and is the same as or lower than energy of emitted laser light. For example, the ohmic layer 70 may be any one selected from AlInGaAs, InGaAs, GaAs, AlInGaAsSb, AlInGaAsPSb, InGaAsP, InGaAsPSb, GaAsSb, InGaAsSb, InAsSb, AlGaAsSb, AlGaAsP, or AlGaInAsP.

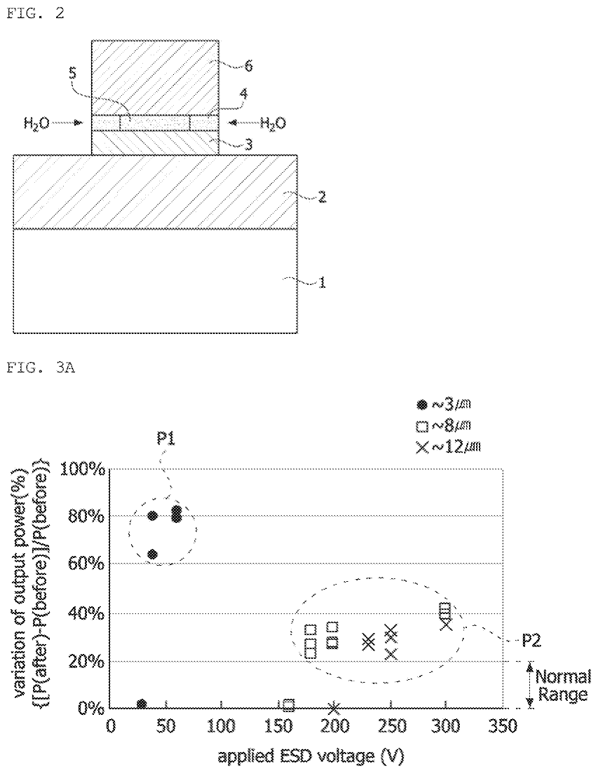

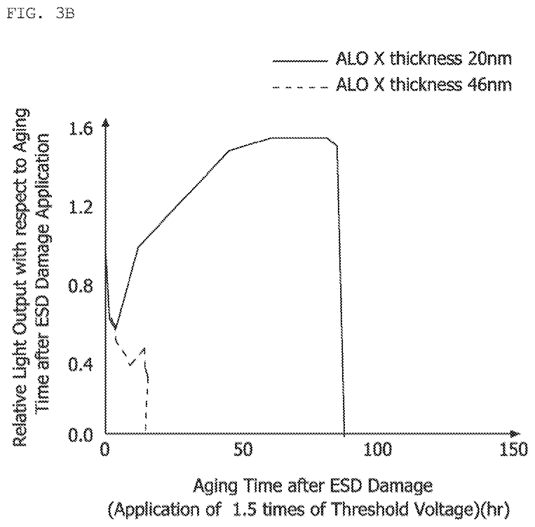

FIG. 2 is a view showing a laser device having an oxide aperture, FIG. 3A is a view showing a light output variation with respect to a size of an oxide aperture, and FIG. 3B is a view showing a light output variation with respect to a thickness of an oxide.

Referring to FIG. 2, a conventional laser structure may include a substrate 1, a lower reflective layer 2, a laser cavity 3, an oxide layer 4, and an upper reflective layer 40. The oxide layer 4 may oxidize sidewalls by exposing them to water vapor. Oxidation may be gradually performed from the sidewalls to the center. The oxidized outer portion may have an increase in a resistance, and the non-oxidized center portion may function as an oxide aperture passing current or light therethrough.

However, the degree of oxidation of the oxide layer 4 may be affected by various conditions such as a composition of a semiconductor compound contained in the oxide layer 4, the orientation of the semiconductor compound, the thickness of the layer 4, the oxidation process, etc. Thus, it may be quite difficult to precisely control the oxide aperture 5. As a result, a manufacturing process may be complex and much time may be required.

On an interfacial surface between the oxide aperture 5 and the oxide layer 4, the density of a defect may increase, resulting in vulnerability to electro static discharge (ESD).

Referring to FIG. 3A, it may be seen that when the size of the oxide aperture is small, the width of reduction of light output sharply increases as an ESD voltage increases. When the size of the oxide aperture is 3 μm (P1), upon application of a voltage of about 50V, 80% of light output may be reduced, whereas when the size of the oxide aperture is 12 μm (P2), a reduction of the light output may be about 40% that is relatively small, in spite of application of a voltage of about 200V.

Referring to FIG. 3B, when the thickness of the oxide layer is about 200 nm, the light output may be maintained for about 80 hours even after occurrence of an ESD damage, whereas when the thickness of the oxide layer is about 46 nm, the light output may sharply decrease within about 10 hours after occurrence of the ESD damage. Thus, the oxide layer may be preferably manufactured relatively thick, but a large thickness of the oxide layer may slow an oxidation speed, increasing an oxidation processing time, such that even an upper reflective layer may be oxidized.

However, according to an embodiment of the present invention, oxidation processing may be omitted, such that there may be few defects in an interface between a through-hole and a blocking structure, being resistant to ESD. A general laser device having an oxide layer has an ESD voltage tolerance of about 200V through about 250V, whereas the laser device according to an embodiment of the present invention may have an ESD voltage tolerance of about 1000V or more. The diameter of the through-hole H1 and the thickness of the blocking structure TR1 may be designed freely.

In a general VCSEL, an effective refractive index difference between a transmitting area in which an aperture 5 is formed by oxidizing the oxide layer 4 and a blocking area in which the oxide layer 4 is oxidized, as shown in FIG. 2, may be about 0.0029. That is, when an effective refractive index difference between the transmitting area and the blocking area is equal to or greater than 0.0029, the blocking area may effectively block light emitted from the laser cavity 3 and concentrate light to the transmitting area.

In general, for an effective refractive index difference of 0.001 or more between the transmitting area and the blocking area, an optical index guiding effect may be obtained. The effective refractive index may be obtained from a difference in the resonance wavelength of a transmittance/reflectivity spectrum between the transmitting area and the blocking area.

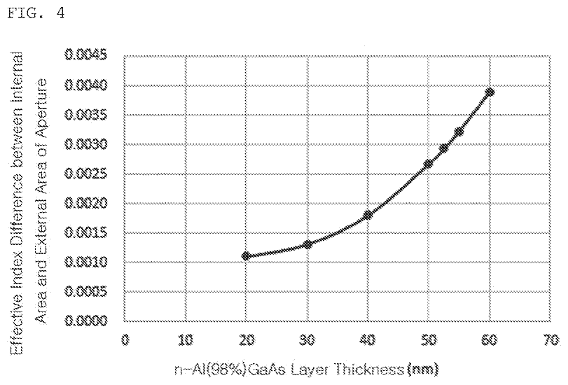

Referring to FIG. 4, it may be seen that as the thickness of a blocking layer that is n-AlGaAs increases, a difference in the effective refractive index between the transmitting area and the blocking area gradually increases.

When the thickness of the blocking layer that is n-AlGaAs is greater than about 50 nm, a difference in the effective refractive index between the transmitting area and the blocking area may be greater than or equal to about 0.0030, such that the blocking layer may function as a blocking area like a general VCSEL. That is, by increasing the thickness without oxidizing the blocking layer that is n-AlGaAs, an optical index guiding effect may be obtained.

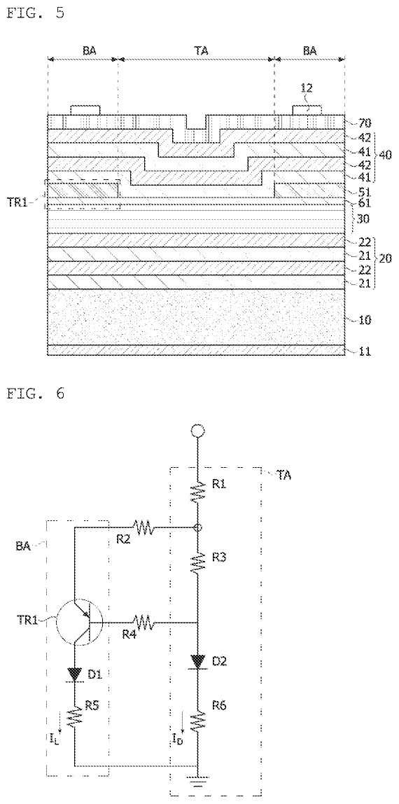

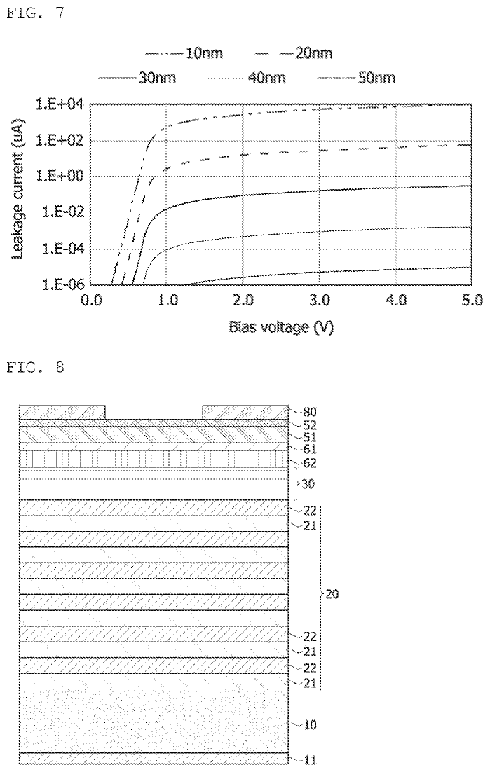

FIG. 5 is a conceptual view of a laser device according to another embodiment of the present invention, FIG. 6 is a circuit diagram of a laser device according to an embodiment of the present invention, and FIG. 7 shows a simulation result of measurement of a leakage current variation with respect to a thickness of a current blocking layer.

Referring to FIG. 5, the blocking structure TR1 may include the first intermediate layer 61 disposed on the laser cavity 30, the blocking layer 51 disposed on the first intermediate layer 61, and a second intermediate layer disposed on the blocking layer 51.

The first intermediate layer 61 may be disposed on the laser cavity 30 to prevent the laser cavity 30 from being exposed when the through-hole H1 is formed in the blocking structure TR1.

At least one sub-intermediate layer may be further disposed between the first intermediate layer 61 and the laser cavity 30. In this case, the through-hole H1 may be formed also in the first intermediate layer 61. Thesub-intermediate layer may be a semiconductor layer that is the same as the upper reflective layer 40.

The blocking layer 51 may be disposed on the first intermediate layer 61, and may be doped with a dopant that is different from that of the first intermediate layer 61. For example, the blocking layer 51 may be any one selected from GaAs, AlGaAs, AlAs, InAlGaAs, InGaP, AlInGaP, AlInP, AlP, GaP, AlGaP, GaAsP, AlGaAsP, or InGaAsP, which is doped with an n-type dopant. When the first intermediate layer 61 is doped with an n-type dopant, the blocking layer 51 may be doped with a p-type dopant.

The second intermediate layer may be a layer 41 disposed in the lowermost portion of the upper reflective layer 40. In the upper reflective layer 40, a plurality of first upper reflective layers 41 and a plurality of second upper reflective layers 42, which have different Al compositions, may be stacked and may be p-type semiconductor layers. Thus, a layer disposed on the lowermost portion of the upper reflective layer 40 may serve as a second intermediate layer of the blocking structure TR1.

The upper reflective layer 40 may be disposed inside the through-hole H1 and thus have a step portion. The step portion may be defined as an area positioned lower than an edge area by being bent by the through-hole H1. The thickness of the step portion may correspond to, but not necessarily limited to, the depth of the through-hole H1.

The step portion of the upper reflective layer 40 may become smaller in a direction away from the blocking structure TR1. As the number of stacks of the upper reflective layer 40 increases, the diameter of the step portion may decrease by the thickness of each layer. Thus, the outermost layer of the upper reflective layer 40 may have a groove with a step.

Referring to FIG. 6, when the laser device according to an embodiment of the present invention is expressed as an equivalent circuit, the blocking structure TR1 may be expressed as a PNP or NPN transistor in the blocking area BA. In this case, a voltage may not be applied to the base, such that the transistor may operate in an OFF state, and thus current may not flow in the transistor. Therefore, leakage current IL flowing in the blocking area BA may be much smaller than driving current I_{D} flowing in the transmitting area TA.

A diode D1 of the blocking area BA and a diode D2 of the transmitting area TA may be pin diodes formed by the laser cavity 30 and semiconductor layers disposed on and under the laser cavity 30. In addition, a plurality of resistors R1, R2, R4, R5, and R6 may be resistors that may be formed by each semiconductor layer and each area. R4 may be designed to have a high resistance because of being formed of p-GaAs and p-AlGaAs with a thin thickness.

Referring to FIG. 7, when the thickness of the blocking layer 51 of the blocking structure TR1 is about 30 nm, a leakage current may be less than 0.1 pA upon application of a voltage of 2V. Thus, it may be seen that when the blocking layer 51 is sufficiently thick, the blocking structure TR1 may sufficiently function as a current blocking layer.

In this case, when the doping concentration of the blocking layer 51 is further increased, the thickness of the blocking layer 51 may be further reduced. The blocking layer 51 may have a doping concentration of about 1×10¹⁷ cm⁻³ through about 1×10²⁰ cm⁻³ and a thickness of about 10 nm through about 100 nm.

FIGS. 8 through 10 are views showing a method for manufacturing a laser device, according to an embodiment of the present invention.

Referring to FIG. 8, the substrate 10, the lower reflective layer 20, the laser cavity 30, and the blocking structure TR1 may be sequentially formed. More specifically, the blocking layer 51 and the second intermediate layer 52 may be formed on the first intermediate layer 61. The above-described features may be applied to characteristics of each layer.

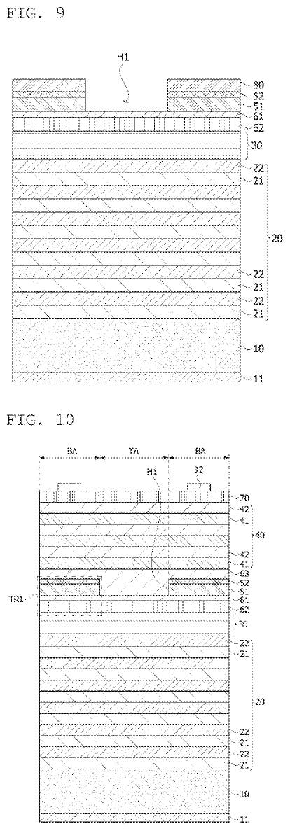

Referring to FIG. 9, a mask 80 may be etched in the blocking structure TR1 to form the through-hole H1 in the center of the blocking structure TR1. The mask 80 may be, but not necessarily limited to, SiO₂, SiₓO_{y}, Si₃N₄, SiₓN_{y}, SiOₓN_{y}, Al₂O₃, TiO₂, AlN or a photoresist.

Referring to FIG. 10, after the third intermediate layer 63 is formed and planarized on the blocking structure TR1, the upper reflective layer 40 may be re-grown. Thus, the blocking structure TR1 may be disposed between the laser cavity 30 and the upper reflective layer 40.

Thereafter, the ohmic layer 70 may be entirely formed on the upper reflective layer 40. The ohmic layer 70 may use a material that has a band gap that is the same as or lower than that of the GaAs substrate 10 and is the same as or lower than energy of emitted laser light.

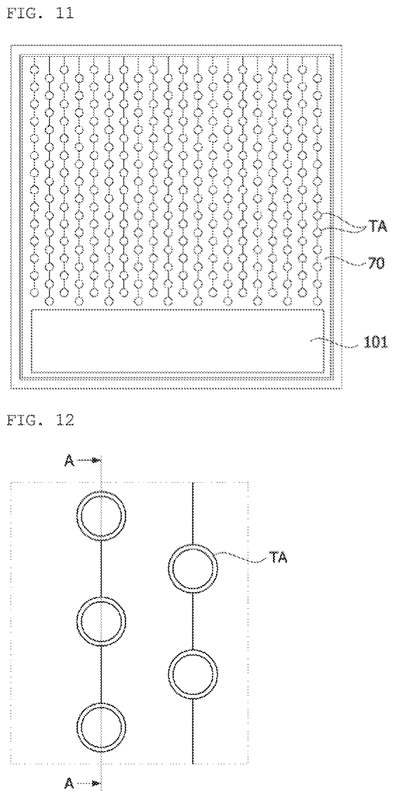

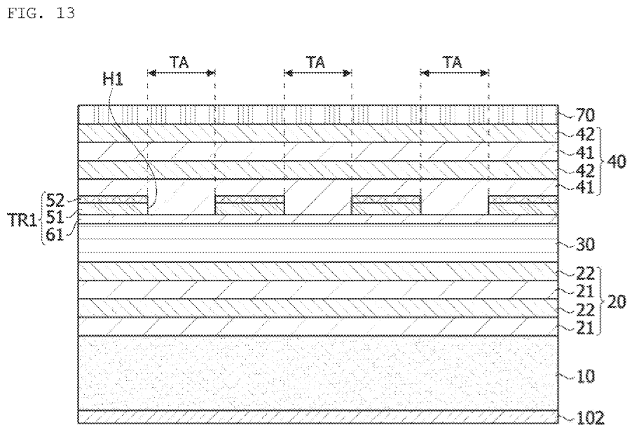

FIG. 11 is a conceptual view of a laser device according to another embodiment of the present invention, FIG. 12 is a partially enlarged view of FIG. 11, and FIG. 13 is a cross-sectional view taken along A-A of FIG. 12.

Referring to FIGS. 11 and 12, a VCSEL according to an embodiment of the present invention may have a plurality of transmitting areas TA arranged in a matrix form. According to an embodiment of the present invention, a hole structure may be omitted that exposes an oxide layer to enable oxidation processing.

The matrix form may be defined as a form where the plurality of transmitting areas TA are arranged separated horizontally to form one line and a plurality of such lines are arranged vertically.

When power is applied to the laser devices in the matrix form, laser light may exit through the transmitting area TA. Thus, a plurality of laser lights may be output from one laser device.

Referring to FIG. 13, a VCSEL according to an embodiment of the present invention may include the substrate 10, the lower reflective layer 20 disposed on the substrate 10, the laser cavity 30 including an active layer disposed on the lower reflective layer 20, the blocking structure TR1 disposed on the laser cavity 30, and the upper reflective layer 40 disposed on the blocking structure TR1.

The blocking structure TR1 may include a plurality of through-holes H1. An area where the plurality of through-holes H1 are formed may be defined as the transmitting area TA, and an area where the blocking structure TR1 is arranged may be defined as the blocking area BA.

Characteristics of the blocking structure TR1 may include those described with reference to FIG. 1. The blocking structure TR1 may have any one of various semiconductor stacking structures such as a PNP type, an NPN type, a PNPN type, an NPNP type, etc. To block current and light in the blocking area BA, the number of layers constituting the blocking structure TR1 may not be specially limited.

A voltage is not applied to the blocking layer 51 corresponding to the base of the transistor, such that the blocking structure TR1 may serve to block the current.

The first intermediate layer 61 may be disposed on the laser cavity 30. The first intermediate layer 61 may be doped with a p-type dopant. The first intermediate layer 61 may be a semiconductor layer that is the same as the upper reflective layer 40. For example, the first intermediate layer 61 may be any one selected from GaAs, AlGaAs, InAlGaAs, AlInGaP, GaAsP, or InGaAsP, doped with a p-type dopant.

The first intermediate layer 61 may be disposed on the laser cavity 30 to prevent the laser cavity 30 from being exposed when the through-hole H1 is formed in the blocking structure TR1. The first intermediate layer 61 may also serve as an etching stop layer.

At least one intermediate sub-layer 62 may be further disposed between the first intermediate layer 61 and the laser cavity 30. In a structure where such an intermediate layer is disposed, the through-hole H1 may be formed also in the first intermediate layer 61. The intermediate sub-layer 62 may be a semiconductor layer that is the same as the upper reflective layer 40.

The first intermediate layer 61 may be a second clad layer disposed on the active layer in the laser cavity 30.

The blocking layer 51 may be disposed on the first intermediate layer 61, and may be doped with a dopant that is different from that of the first intermediate layer 61. For example, the blocking layer 51 may be any one selected from GaAs, AlGaAs, AlAs, InAlGaAs, InGaP, AlInGaP, AlInP, AlGaP, GaAsP, AlP, ZnSe, ZnSeS, or InGaAsP, which is doped with an n-type dopant. When the first intermediate layer 61 is doped with an n-type dopant, the blocking layer 51 may be doped with a p-type dopant.

The second intermediate layer 52 may be disposed on the blocking layer 51. A dopant doped in the second intermediate layer 52 may be the same as that of the first intermediate layer 61, but may be different from that of the blocking layer 51. For example, the second intermediate layer 52 may be any one selected from GaAs, AlGaAs, InAlGaAs, InGaP, AlInGaP, GaP, GaAsP, or InGaAsP, doped with a p-type dopant.

The through-hole H1 formed in the blocking structure TR1 may be formed only in the blocking layer 51, but may also be formed in the blocking layer 51 and the second intermediate layer 52, without being necessarily limited to the above. Alternatively, the through-hole H1 may perforate all of the first intermediate layer, the blocking layer, and the second intermediate layer.

The laser device according to the current embodiment of the present invention may be used as a light source for 3D face recognition and 3D imaging techniques. The 3D face recognition and 3D imaging techniques require a light source matrix patterned in a 2D array form. Such a light source matrix patterned in the 2D array form may be irradiated to an object and a pattern of reflected light may be analyzed. In this case, by analyzing deformed states of element lights reflected from a curved surface of each form object in the light source matrix patterned in the 2D array form, a 3D image of an object may be formed. By manufacturing a VCSEL array according to an embodiment of the present invention with such a structured light source patterned in the 2D array form, the structured light source matrix patterned in the 2D array form may be provided where characteristics of each element light source are uniform.

The laser device according to the present invention may be used as a low-price VCSEL light source in many application fields such as an optical communication device, a closed-circuit television (CCTV), a night vision for a vehicle, motion recognition, medical treatment, a communication device for Internet of Things (IoT), a heat tracking camera, a thermal imaging camera, a pumping field of a solid-state laser (SOL), a heating process for bonding plastic films, etc.

According to an embodiment of the present invention, the reliability of the laser device may be improved as the resistance of the laser device to ESD becomes strong.

Moreover, a process of forming the oxide aperture may be omitted, thereby simplifying a manufacturing process of the laser device.

Various and useful advantages and effects of the present invention are not limited to the foregoing description, and may be more easily understood in a process of describing detailed embodiments of the present invention.

While the embodiments have been described, they are merely examples and do not limit the present invention, and it would be understood by those of ordinary skill in the art that several modifications and applications not described above are possible without departing the essential characteristics of the current embodiment. For example, each component described in detail in the embodiment may be carried out by being modified. Differences related to such modifications and applications should be interpreted as falling within the scope of the present invention defined in the appended claims.

What is claimed is:

1. A laser device comprising:
a lower reflective layer;
a laser cavity comprising an active layer disposed on the lower reflective layer;
an upper reflective layer disposed on the laser cavity; and
a blocking structure disposed between the laser cavity and the upper reflective layer,
wherein the blocking structure comprises:
a first intermediate layer disposed on the laser cavity;
a blocking layer disposed on the first intermediate layer and comprising a through-hole; and
a second intermediate layer disposed on the blocking layer.

2. The laser device of claim 1, wherein the first intermediate layer, the second intermediate layer, and the blocking layer comprise any one of a dopant doped in the lower reflective layer or a dopant doped in the upper reflective layer,
the first intermediate layer and the second intermediate layer comprise a same dopant, and
the blocking layer comprises a dopant that is different from a dopant of the first intermediate layer.

3. The laser device of claim 1, wherein a thickness of the second intermediate layer is less than a thickness of the blocking layer, and
an aluminum composition of the blocking layer is higher than an aluminum composition of the second intermediate layer.

4. The laser device of claim 1, further comprising a third intermediate layer disposed on the second intermediate layer,
wherein the third intermediate layer comprises a first area disposed on the second intermediate layer and a second area disposed on the through-hole.

5. The laser device of claim 4, wherein a thickness of the blocking layer is greater than a thickness of the first area and is less than a thickness of the second area.

6. The laser device of claim 4, wherein a top surface of the third intermediate layer comprises a flat surface.

7. The laser device of claim 1, wherein the second intermediate layer is a lowermost layer of the upper reflective layer.

8. The laser device of claim 1, wherein the first intermediate layer is a p-type semiconductor layer, the blocking layer is an n-type semiconductor layer, and the second intermediate layer is a p-type semiconductor layer.

9. The laser device of claim 1, wherein the first intermediate layer is an n-type semiconductor layer, the blocking layer is a p-type semiconductor layer, and the second intermediate layer is an n-type semiconductor layer.

10. The laser device of claim 3, wherein oxidation degrees of the first intermediate layer, the blocking layer, and the second intermediate layer may be less than or equal to 10%.

11. The laser device of claim 1, wherein the through-hole is provided in plural.

12. The laser device of claim 1, further comprising a blocking area where the blocking layer and the upper reflective layer overlap with each other and a transmitting area where the through-hole and the upper reflective layer overlap with each other, and
an effective refractive index difference between the blocking area and the transmitting area is greater than or equal to 0.001.
